(19) United States
(12) Patent Application Publication
(10) Pub. No.: US 2008/0130226 A1
(43) Pub. Date: Jun. 5, 2008

(54) CENTRIFUGAL FAN DEVICE AND ELECTRONIC APPARATUS HAVING THE SAME

(75) Inventors: Akitomo YAMASHITA, Oita (JP); Seiki ISHIDA, Oita (JP)

Correspondence Address: DICKINSON WRIGHT PLLC, 1901 L STREET NW, SUITE 800, WASHINGTON, DC, 20036, US

(73) Assignee: MATSUSHITA ELECTRIC INDUSTRIAL CO., LTD., OSAKA (JP)

(21) Appl. No.: 11/947,739

(22) Filed: Nov. 29, 2007

(30) Foreign Application Priority Data
Nov. 30, 2006 (JP) 2006-323401
Mar. 29, 2007 (JP) 2007-087466

(51) Int. Cl. H05K 7/20; F04D 29/54

(52) U.S. Cl. 361/695; 415/119; 415/203

(57) ABSTRACT

A centrifugal fan device includes a centrifugal fan having a hub portion having a cylindrical outer peripheral surface and a plurality of blade portions extended in a centrifugal direction from the outer peripheral surface of the hub portion, and a fan casing which rotatably accommodates the centrifugal fan therein and includes a pair of inlets having an equal diameter and disposed opposite to each other with the centrifugal fan interposed therebetween, a convex portion is provided on a positive pressure face of the blade portion for receiving a wind when the blade portion is rotated, and one of ends of the convex portion is disposed on an inside of a projection region of the blade portion surrounded by an outer periphery of the inlet projected onto the blade portion and the other end of the convex portion is disposed on an outside of the projection region and an inside separated from a tip of the blade portion by a first predetermined distance.

### BACKGROUND

The present invention relates to a centrifugal fan device to be used for cooling a heat generator such as a micro processor unit (which will be hereinafter referred to as an MPU) mounted in a housing of an electronic apparatus and to a centrifugal fan device for efficiently transporting a heat from a heating member to a radiator by a method such as a heat pipe or a circulation of a liquid refrigerant and then forcibly sending an air and cooling the radiator, and an electronic apparatus having the centrifugal fan device.

There has been a very quick trend for an increase in a speed of a data processing in a recent computer, and a clock frequency of an MPU has been increased to be considerably greater than ever.

As a result, a quantity of heat generation of the MPU is increased so that a method of forcibly cooling a heat sink and a radiator fin by air blowing of a fan, a method of cooling a radiating portion by means of a fan in a heat sink module which is thermally connected to the radiating portion using a heat pipe through a heating portion, and a furthermore, a method of forcibly circulating a liquid refrigerant having a high thermal conductivity by means of a pump and forcedly sending the air to a radiator subjected to a heat transportation between the heating portion and the radiating portion by a centrifugal fan device and radiating a heat are indispensable in addition to a method of causing a heating surface of a radiator such as a heat sink or a radiator fin to come in contact with a heat generator and radiating a heat as in the conventional art. An enhancement in a cooling capability and a reduction in a size will further be required in the future.

On the other hand, the enhancement in the cooling capability of the centrifugal fan device greatly depends on an enhancement in an air blowing capability such as an increase in an air flow or a rise in a static pressure. In general, it is possible to improve the air blowing capability of the centrifugal fan device by increasing a rotating speed. To the contrary, an air cutting sound (which will be hereinafter referred to as a fan noise) of a blade portion in the centrifugal fan device also tends to be increased. For this reason, various shapes of the blade portion have been proposed for reducing the fan noise.

FIG. 16(a) is a plan view showing a blade portion taking a shape of a wing in a centrifugal fan device according to the prior art and FIG. 16(b) is a perspective view showing the blade portion taking the shape of a wing in the centrifugal fan device according to the prior art.

The centrifugal fan device is of a multi-vane type in which a large number of blade portions are disposed in a circumferential portion such as a cross flow fan or a sirocco fan and is characterized in that blade portions 91 taking a shape of a wing are arranged almost radially in a direction of a circumference around a rotating axis and an air flow is generated in a centrifugal direction by a rotation of the blade portion 91, and each of the blade portions 91 has a predetermined thickness, length and height on only a positive pressure face to be a pressure face for receiving a positive pressure or both the positive pressure face and a negative pressure face on a back side of the positive pressure face in the vicinity of an end at an outside in a radial direction and a plurality of ribs 92 is arranged in parallel with each other at a predetermined interval with a longitudinal direction set to be a direction of the air flow, that is, a longitudinal direction of the blade portion 91.

By the structure, a disorder of the air flow in the vicinity of a rear edge of the blade portion 91 is rectified so that a vortex interference in a span direction at the rear edge of the blade portion 91 is reduced. As a result, a wideband frequency noise is suppressed so that a noise can be reduced considerably. Therefore, it is possible to produce an advantage that the structure is suitable for an indoor machine of air equipment (for example, see Patent Document 1).

In another prior art, moreover, there has also been proposed a shape of a blade portion having a projection provided on an end at an inner diameter side of a surface (a negative pressure face) on an opposite side to a rotating direction of the blade portion in a centrifugal fan device of a multi-vane type in which a large number of blade portions are disposed in a circumferential portion such as a cross flow fan or a sirocco fan.

The projection disturbs an air flow entering a part between the blade portions, a hydrodynamic boundary layer (a separating bubble) generated on the inner diameter side of the blade portion is prevented from being grown, and the air is prevented from being blown out at the outer diameter side of the blade portion with a separation from the negative pressure face, and the separating air is caused to easily stick to the negative pressure face again, thereby reducing an abnormal sound having a low frequency (for example, see Patent Document 2).

In yet another prior art, furthermore, there has also been proposed a centrifugal fan device comprising a centrifugal fan constituted by a hub portion formed to cover a motor driving portion and a plurality of blade portions formed integrally with the hub portion.

The blade portion of the centrifugal fan is constituted by a vane and an arm portion for supporting the vane, a length in an axial direction of the arm portion is set to be smaller than a length (a width) in an axial direction of the vane in such a manner that a sufficient clearance is formed between internal surfaces of lower and upper walls of a fan casing, and the vane has such a structure that four pairs of concavo-convex portions are provided on each of upper and lower ends in a radial direction thereof.

The vane has a plurality of concavo-convex portions provided on each of the upper and lower ends in the radial direction. Therefore, a disorder is forcibly induced into a flow of a slip stream vortex air generated on the upper and lower ends in the radial direction so that a turbulence diffusion is promoted and the slip stream vortex is reduced, resulting in a decrease in a fan noise (for example, see Patent Document 3).

Furthermore, FIG. 17 is a perspective view showing the centrifugal fan according to the prior art.

As shown in FIG. 17, there has also been proposed a structure in which a convex surface 95 and a concave surface 96 are formed on two faces of each blade portion 94 taking a shape of an arc outward from a peripheral edge of a hub portion 93, and a channel portion 97 which is convexed reversely to the concave surface 96 of the blade portion 94 is provided on the convex surface 95. At least one arcuate surface 98 is formed in a position in which the channel portion 97 and the blade portion 94 are coupled to each other (for example, see Patent Document 4).

[Patent Document 1] JP-A-9-126190 Publication

[Patent Document 2] JP-A-2002-115694 Publication

[Patent Document 3] JP-A-2004-353496 Publication

[Patent Document 4] Japanese Utility Model Publication No. 3081775

However, the conventional structures described in the (Patent Document 1) and the (Patent Document 2) have the function of controlling a flow of an air sucked from only one of inlets in the direction of the rotating shaft of the blade portion and flowing in the centrifugal direction along the surface of the blade portion, thereby reducing a vortex interference in a span direction in the vicinity of the rear edge of the blade portion and the function of preventing a separation from the negative pressure face in the vicinity of the rear edge of the blade portion. For this reason, particularly, it is an object to reduce fan noises and abnormal sounds which are caused by the air flow in the vicinity of the rear edge of the blade portion, that is, the vicinity of an outer diameter side end of the blade portion.

With the conventional structure described in the (Patent Document 3), moreover, the air is sucked from both parts in the direction of the rotating axis of the blade portion and flows in the centrifugal direction of the blade portion. However, it is an object to control the air flow, thereby reducing fan noises and abnormal sounds which are caused by the air flow in the vicinity of the upper and lower ends positioned on both ends in the direction of the rotating axis of the blade portion.

In other words, with the structures according to the prior arts, it is an object to reduce fan noises and abnormal sounds which are generated when the air sucked once into the fan casing and flowing over the surface of the blade portion leaves the outer diameter side end of the blade portion or the upper and lower ends, and there is no function of suppressing a vortex flow or a turbulence which is generated by a collision and a mutual interference over the surface of the blade portion positioned in the air sucking region in the case in which the air is sucked in different directions from each other as when the air is sucked from both of the inlets in the direction of the rotating axis of the centrifugal fan. For this reason, there is a problem in that fan noises or abnormal sounds are generated in the air sucking region.

On the other hand, with the conventional structure described in the (Patent Document 4), the channel portion is formed continuously and uniformly from the outer peripheral surface of the hub portion to the tip of the blade portion. Therefore, it is possible to reduce the fan noises or abnormal sounds caused by the generation of the vortex flow or the turbulence in the air sucking region to some degree. At the outer diameter side of the blade portion in the fan casing which is an outside of the air sucking region, however, the channel portion rather functions as an air course resistor and a confluence of parallel flows of the air in the centrifugal direction over the surface of the blade portion is suppressed. For this reason, there is also a problem in that an efficient blast is inhibited and a sufficient air quantity cannot be obtained.

If the other end of the convex portion has such a length as to be extended to the tip of the blade portion at the outside of the projection region, moreover, the convex portion is present in a place in which a centrifugal force is generated most greatly in the blade portion. Therefore, a force for causing the blade portion to catch and push out a wind is reduced so that an air quantity generated by the centrifugal fan is decreased. Furthermore, the convex portion is resistant to a flow of an incoming wind through the inlet. For this reason, there is a problem in that the air quantity generated by the centrifugal fan is reduced.

### SUMMARY

In order to solve the conventional problems, it is an object of the invention to provide a centrifugal fan device capable of implementing a reduction in fan noises and abnormal sounds and an increase in an air quantity at the same time by suppressing a collision and a mutual interference of airs sucked in opposite directions to each other from respective inlets in an air sucking region over a surface of a blade portion and reducing an air course resistance at an outside of the air sucking region and smoothly joining parallel flows of the air over a surface of the blade portion to cause the air to smoothly flow in a centrifugal direction, and an electronic apparatus having the centrifugal fan device.

In order to solve the conventional problems, a centrifugal fan device according to the invention comprises a centrifugal fan including a hub portion having a cylindrical outer peripheral surface and a plurality of blade portions extended in a centrifugal direction from the outer peripheral surface of the hub portion, and a fan casing which rotatably accommodates the centrifugal fan therein and includes a pair of inlets having an equal diameter and disposed opposite to each other with the centrifugal fan interposed therebetween, wherein a convex portion is provided on a positive pressure face of the blade portion for receiving a wind when the blade portion is rotated, and one of ends of the convex portion is disposed on an inside of a projection region of the blade portion surrounded by an outer periphery of the inlet projected onto the blade portion and the other end of the convex portion is disposed on an outside of the projection region and an inside separated from a tip of the blade portion by a first predetermined distance.

By the structure, the convex portion acts as a distributing plate of each air sucked from a pair of inlets disposed opposite to each other so that it is possible to prevent the airs sucked in opposite directions to each other from mutually interfering with a collision over the surface of the blade portion and to cause the respective airs to smoothly flow in the centrifugal direction. Therefore, it is possible to implement a reduction in fan noises and abnormal sounds which are caused by the generation of a vortex flow or a turbulence in an air sucking region.

In addition, it is also possible to implement an increase in an air quantity at the same time by reducing an air course resistance at the outside of the air sucking region to smoothly join parallel flows of the air over the surface of the blade portion and to cause the air to smoothly flow in the centrifugal direction.

In other words, in comparison on an equal fan noise level, a rotating speed can be increased more greatly. Therefore, an increase in an air quantity and a rise in a static pressure can easily be carried out so that an air blowing capability can be enhanced.

### BRIEF DESCRIPTION OF THE DRAWINGS

FIG. 1(a) is a perspective view showing a centrifugal fan device according to a first embodiment of the invention as seen from above and FIG. 1(b) is a perspective view showing a state in which a cover of the centrifugal fan device according to the first embodiment of the invention is removed as seen from above,

FIG. 2(a) is a plan view showing the centrifugal fan device according to the first embodiment of the invention and FIG. 2(b) is a sectional view taken along a line A-A in (a),

FIG. 3 is a plan view showing the centrifugal fan according to the first embodiment of the invention,

FIG. 4(a) is a perspective view showing the centrifugal fan according to the first embodiment of the invention and FIG. 4(b) is a view showing a cylindrical sectional shape of a blade portion of the centrifugal fan according to the first embodiment of the invention,

FIG. 5(a) is a partial enlarged perspective view showing the blade portion of the centrifugal fan according to the first embodiment of the invention and FIG. 5(b) is a partial enlarged plan view showing the blade portion of the centrifugal fan according to the first embodiment of the invention,

FIG. 6 is a comparative graph for a fan noise (A range noise) in an equal air quantity,

FIG. 7 is a comparative graph for an air quantity and static pressure characteristic in an identical fan noise,

FIG. 8(a) is a partial enlarged perspective view showing a blade portion of a centrifugal fan according to a second embodiment of the invention and FIG. 8(b) is a partial enlarged plan view showing the blade portion of the centrifugal fan according to the second embodiment of the invention,

FIG. 9 is a graph showing an air quantity and a fan noise with respect to a ratio of a length of the blade portion positioned on an outside of a projection area region of an inlet to a distance from a tip of the blade portion to a starting point of a convex portion,

FIG. 10 is a perspective view showing a centrifugal fan according to a third embodiment of the invention,

FIG. 11(a) is a partial enlarged perspective view showing a blade portion of the centrifugal fan according to the third embodiment of the invention and FIG. 11(b) is a partial enlarged plan view showing the blade portion of the centrifugal fan according to the third embodiment of the invention,

FIG. 12(a) is a front view showing the blade portion of the centrifugal fan according to the third embodiment of the invention as seen from a positive pressure face side and FIG. 12(b) is a plan view showing the blade portion of the centrifugal fan according to the third embodiment of the invention as seen from just above,

FIG. 13 is a comparative graph for a fan noise (A range noise) in an equal air quantity,

FIG. 14 is a comparative graph for an air quantity and static pressure characteristic in the case in which an identical fan casing and an identical driving circuit are used,

FIG. 15(a) is a view showing an inner part of a housing of an electronic apparatus according to a fourth embodiment of the invention and FIG. 15(b) is a partial sectional view showing the inner part of the housing of the electronic apparatus according to the fourth embodiment of the invention,

FIG. 16(a) is a plan view showing a blade portion taking a shape of a wing in a centrifugal fan device according to the prior art and FIG. 16(b) is a perspective view showing the blade portion taking the shape of a wing in the centrifugal fan device according to the prior art, and

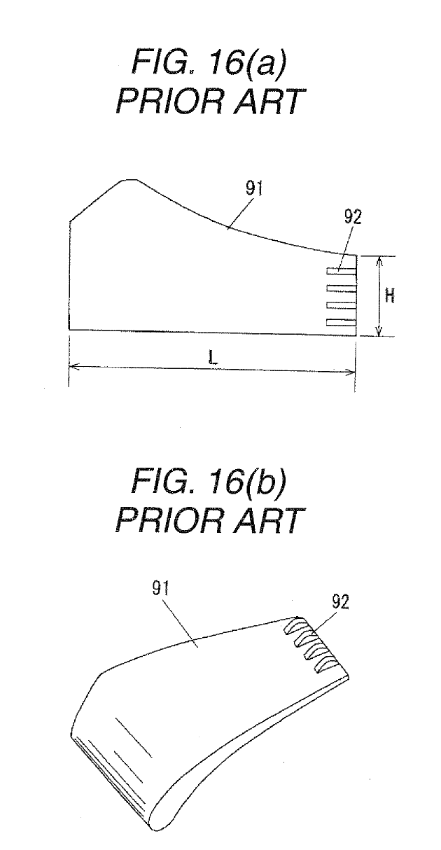

FIG. 17 is a perspective view showing a centrifugal fan according to the prior art.

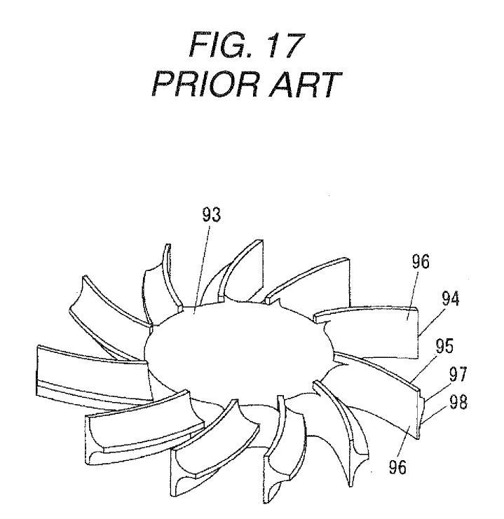

### DETAILED DESCRIPTION

The best mode for carrying out the invention will be described below with reference to the drawings.

### First Embodiment

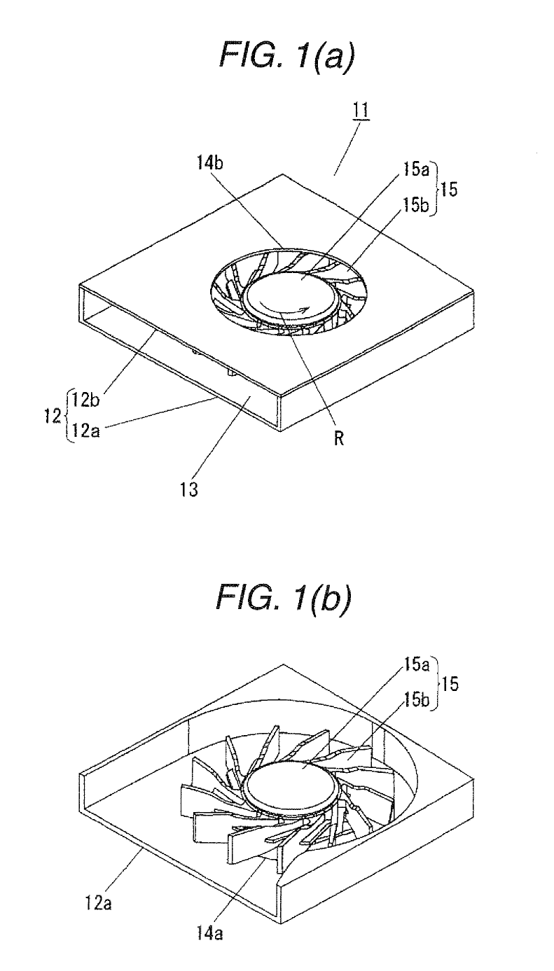

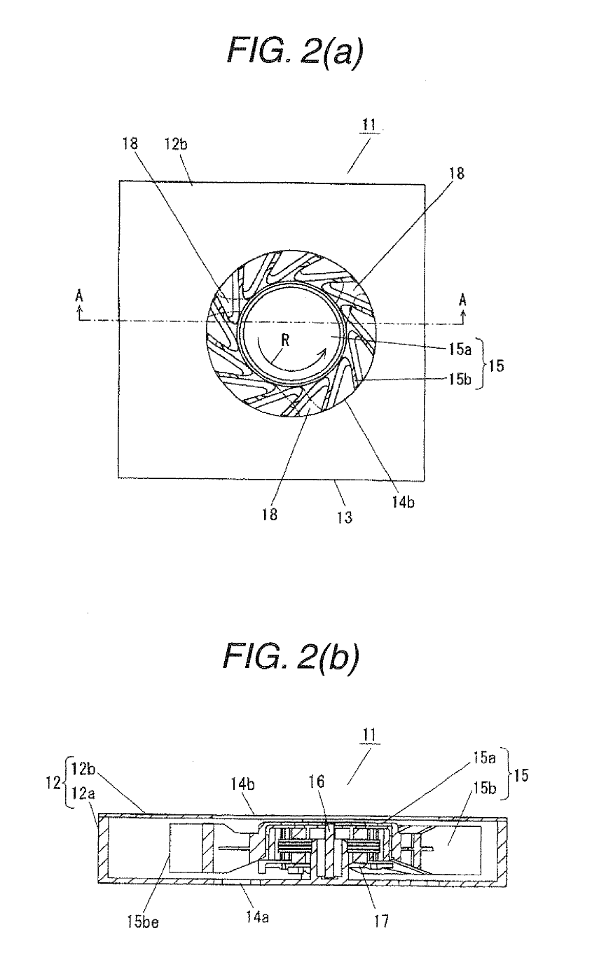

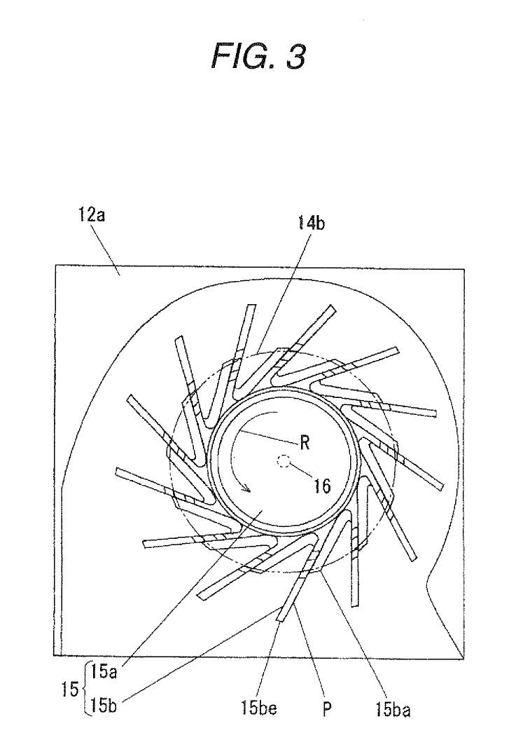

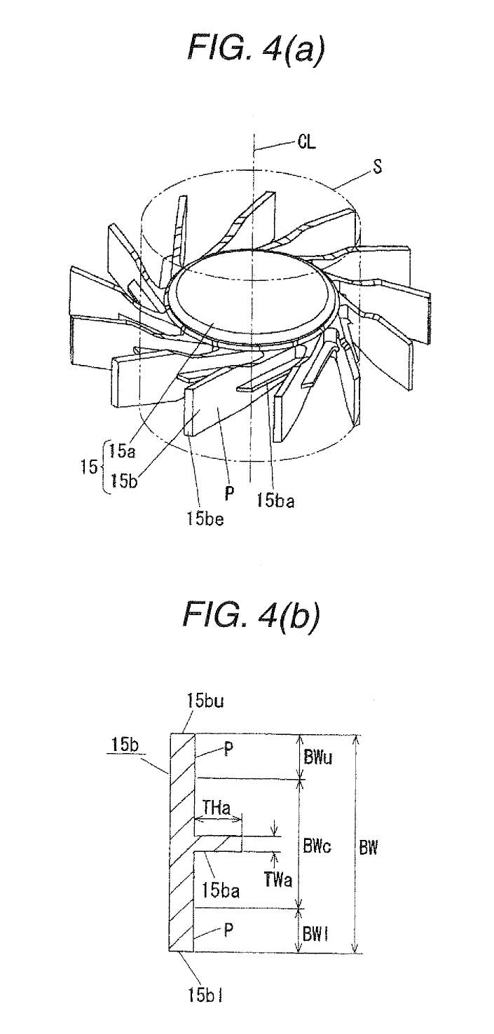

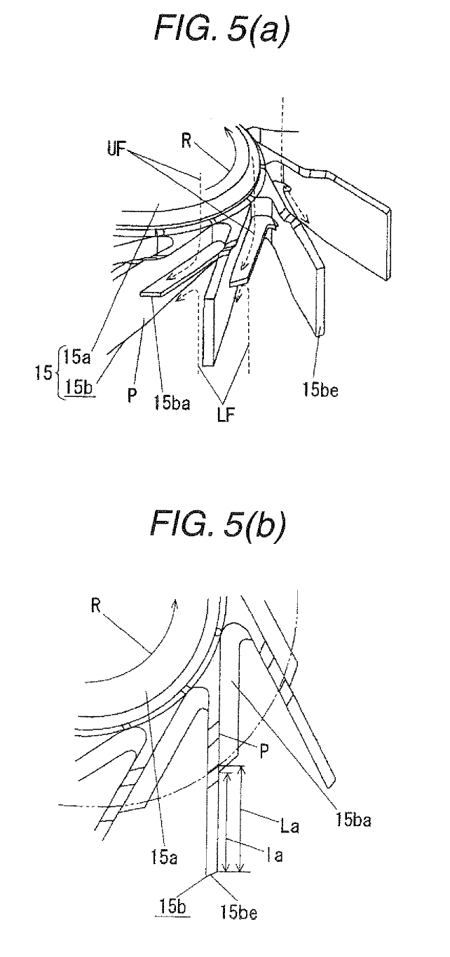

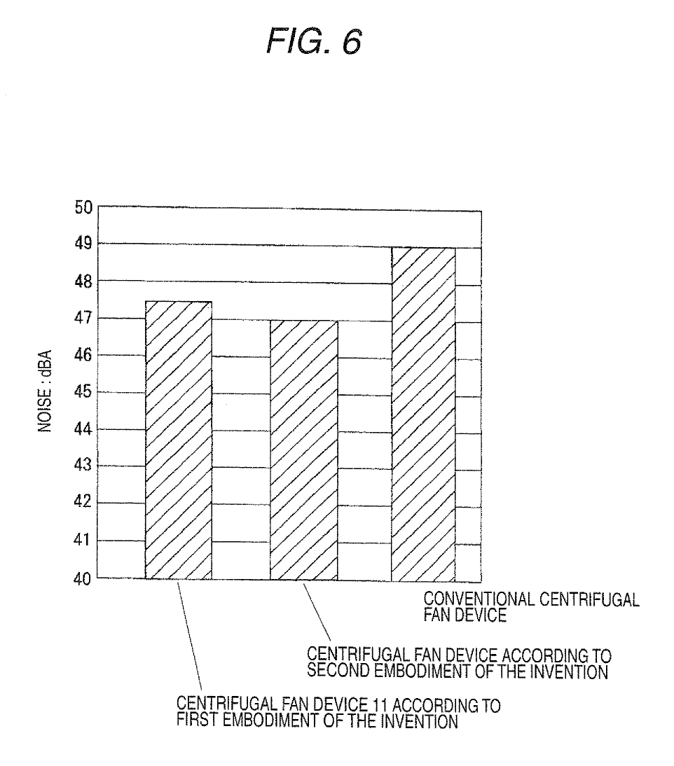

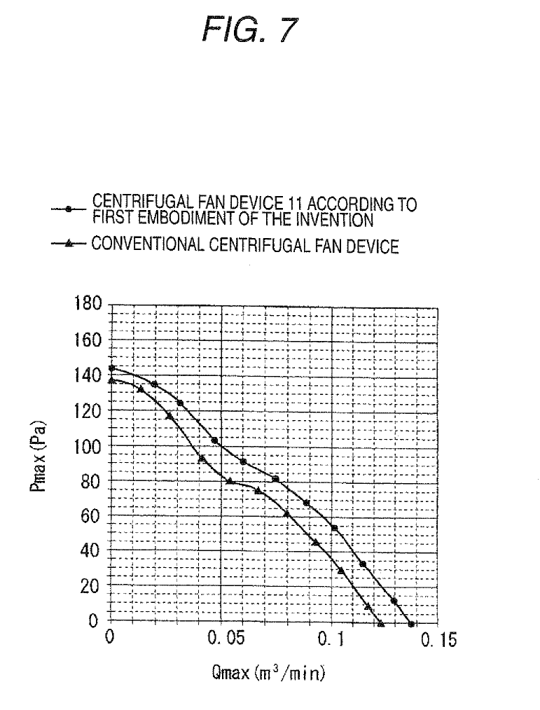

FIG. 1(a) is a perspective view showing a centrifugal fan device according to a first embodiment of the invention as seen from above, FIG. 1(b) is a perspective view showing a state in which a cover of the centrifugal fan device according to the first embodiment of the invention is removed as seen from above, FIG. 2(a) is a plan view showing the centrifugal fan device according to the first embodiment of the invention, FIG. 2(b) is a sectional view taken along a line A-A in (a), FIG. 3 is a plan view showing the centrifugal fan according to the first embodiment of the invention, FIG. 4(a) is a perspective view showing the centrifugal fan according to the first embodiment of the invention, FIG. 4(b) is a view showing a cylindrical sectional shape of a blade portion of the centrifugal fan according to the first embodiment of the invention, FIG. 5(a) is a partial enlarged perspective view showing the blade portion of the centrifugal fan according to the first embodiment of the invention, FIG. 5(b) is a partial enlarged plan view showing the blade portion of the centrifugal fan according to the first embodiment of the invention, FIG. 6 is a comparative graph for a fan noise (an A range noise) in an equal air quantity, and FIG. 7 is a comparative graph for an air quantity and static pressure characteristic in an identical fan noise.

First of all, as shown in FIG. 1(a), a fan casing 12 of a centrifugal fan device 11 is constituted by a frame 12a positioned in a lower part and a cover 12b positioned an upper part.

In the frame 12a, a bottom wall and a side wall are formed integrally by means of a resin mold or a die casting mold formed by an aluminum alloy, and an outlet 13 for discharging an air sucked into the fan casing 12 to an outside is provided on one of side surfaces and an almost circular inlet 14a is provided on a bottom wall thereof as shown in FIG. 1(b).

On the other hand, the cover 12b is formed like a plate by a punching mold formed by a metallic material such as steel, aluminum or copper or a resin mold, and an almost circular inlet 14b for sucking an air is provided in a central part thereof.

Moreover, the fan casing 12 rotatably accommodates a centrifugal fan 15 and has a pair of inlets 14a and 14b to be disposed opposite to each other with the centrifugal fan 15 interposed therebetween.

Furthermore, the centrifugal fan 15 includes a hub portion 15a having a cylindrical outer peripheral surface and a plurality of plate-shaped blade portions 15b extended from the outer peripheral surface in a centrifugal direction.

When the centrifugal fan 15 is rotated at a high speed in a direction designated as a rotating direction R, accordingly, an outside air is sucked from both the inlet 14b positioned above the hub portion 15a of the centrifugal fan 15 and the inlet 14a positioned below the hub portion 15a of the centrifugal fan 15.

The respective airs sucked from the inlets 14a and 14b are sucked in opposite directions to each other in a direction of a rotating shaft 16 (see FIG. 2(b)) of the centrifugal fan 15 which will be described below, and furthermore, a direction of the sucked air is rapidly changed into the centrifugal direction of the plate-shaped blade portions 15b in the fan casing 12 by a rotating motion of the blade portion 15b. Therefore, most of the airs also collide with the internal walls of the frame 12a and the cover 12b at the same time, and are fed in the same direction as the rotating direction of the centrifugal fan 15 along the internal walls and are finally discharged from the outlet 13 to the outside.

As shown in FIGS. 2(a) and 2(b), the centrifugal fan device 11 comprises the centrifugal fan 15 including the hub portion 15a having the cylindrical outer peripheral surface and the plate-shaped blade portions 15b extended in the centrifugal direction from the outer peripheral surface as described above, the rotating shaft 16 fixed to a center on an inside of the hub portion 15a, a motor driving portion 17 disposed to be covered with the hub portion 15a below the hub portion 15a and serving to apply a rotating and driving force to the rotating shaft 16, the frame 12a for holding the motor driving portion 17 from below, and the cover 12b constituting the fan casing 12 in combination with the frame 12a, and the fan casing 12 is rotatably accommodated to surround the centrifugal fan 15.

As is apparent from FIG. 2(b), moreover, both the inlet 14b disposed on the cover 12b and the inlet 14a disposed on the bottom wall of the frame 12a are designed to take an almost circular shape having an equal radius around the rotating shaft 16. Furthermore, the inlet 14a and the outlet 14b are disposed opposite to each other with the centrifugal fan 15 interposed therebetween.

The motor driving portion 17 is constituted by a circuit board in which a motor driving circuit for applying the rotating and driving force to the rotating shaft 16 is incorporated. The motor driving portion 17 is held through three coupling portions 18 extended from the frame 12a to cross the inlet 14a disposed on the bottom wall of the frame 12a in an orthogonal direction to an air sucking direction thereof (see FIG. 2(a)).

The fan casing 12 having the frame 12a positioned in a lower part and the cover 12b positioned in an upper part in combination in a vertical direction is accommodated to surround the outer peripheral part of the blade portion 15b of the centrifugal fan 15. Therefore, the centrifugal fan 15 is rotated in a direction designated as a rotating direction R of FIG. 2(a) so that a necessary static pressure for a blast can be generated.

As is apparent from the drawing, on the assumption that the three coupling portions 18 extended to cross the inlet 14a of the frame 12a are omitted, projection area regions of the respective inlets 14a and 14b can be regarded to be almost equal to each other with respect to the centrifugal fan 15 because the inlets 14a and 14b are formed to have an identical center, an equal radius and an almost circular shape.

In the case in which a pair of inlets having an equal diameter is disposed opposite to each other with the centrifugal fan interposed therebetween in the fan casing, a quantity of the wind sucked from the inlet by the rotation of the centrifugal fan is increased close to an edge of the inlet because an air pressure is dropped toward an outside of the centrifugal fan, and is reduced close to the center of the centrifugal fan by a centrifugal force. As a result, winds in large quantities enter the fan casing from both upper and lower parts of the centrifugal fan and collide with each other in the vicinity of the edge of the inlet. Therefore, a noise is made, and furthermore, the air quantity is reduced so that the function of the centrifugal fan is deteriorated.

According to the example, a convex portion is provided in a corresponding position to the outer periphery of the inlets having an equal diameter over the positive pressure face of the blade portion for receiving the wind when the blade portion is rotated, and one of ends of the convex portion is provided on an inside of a projection region of the blade portion surrounded by the outer periphery of the inlet projected onto the blade portion. On the other hand, the other end of the convex portion is provided on an outside of the projection region. Also in the case in which a fan casing including a pair of inlets having an equal diameter and disposed opposite to each other with the centrifugal fan interposed therebetween is used, therefore, winds in large quantities and generated in the vicinity of the edge of the inlet are prevented from colliding with each other through both the upper and lower parts. Consequently, it is possible to prevent the generation of a noise and to prevent the air quantity from being reduced, thereby maintaining the function of the centrifugal fan.

FIG. 3 shows an external shape of the frame 12a and a side wall of the frame 12a which is positioned on an outer diameter side of the blade portion 15b in a solid line and the inlet 14b in a two-dotted chain line, in which a positional relationship between the centrifugal fan 15 and the inlet 14b can easily be understood.

A region in a circle of the inlet 14b shown in the two-dotted chain line is a projection area region obtained by projecting an open region of the inlet 14b provided on the cover 12b in a direction of the centrifugal fan 15 in parallel with a direction of the rotating shaft 16, and a convex portion 15ba is formed on a surface in the direction designated as the rotating direction R of all of the blade portions 15b positioned in at least the region (which will be hereinafter referred to as a positive pressure face P).

The convex portion 15ba is positioned on an almost center in a transverse direction in the positive pressure face P and is started in a position on an inner diameter side by a predetermined distance from a tip 15be of the blade portion 15b at an outside of the projection area region of the inlet 14b, is extended into the projection area region of the inlet 14b and is linked to the outer peripheral surface of the hub portion 15a, which will be described below in detail.

Accordingly, the convex portion 15ba formed on each blade portion 15b functions as a distributing plate for an air sucked from each of the inlets 14a and 14b disposed opposite to each other so that the airs sucked in exactly reverse directions to each other can be prevented from colliding and interfering with each other over the positive pressure face P of the blade portion 15b and each air can be caused to smoothly flow in the centrifugal direction. Therefore, it is possible to implement a reduction in fan noises and abnormal sounds which are caused by the generation of a vortex flow or a turbulence in the air sucking region.

In addition, it is possible to simultaneously implement an increase in the air quantity by reducing an air course resistance and smoothly joining the parallel flows of the air over the positive pressure face P of the blade portion 15b to cause the air to smoothly flow in the centrifugal direction in a region provided on an outside of the air sucking region.

In a comparison on an equal fan noise level, moreover, a rotating speed can be increased more greatly. Consequently an increase in an air quantity and a rise in a static pressure can easily be carried out so that an air blowing capability can be enhanced.

It is preferable that the convex portion should be formed to be started in a position on an inner diameter side from the tip 15be of the blade portion 15b by a longer distance by 20% than a length on the positive pressure face P side of the blade portion 15b positioned on the outside of the projection area region of either of the inlets. An air course resistance in a region provided on the outside of the air sucking region can be effectively reduced and the parallel flows of the air can be smoothly joined over the surface of the blade portion to cause the air to smoothly flow in the centrifugal direction. Therefore, the air quantity can be increased more greatly.

As is apparent from the drawing, similarly, each convex portion 15ba is started in the position on the inner diameter side by a predetermined distance from the tip 15be of the blade portion 15b and is extended into the projection area region of the inlet 14b over the positive pressure face P of the blade portion 15b, and is linked to the outer peripheral surface of the hub portion 15a.

If radii or central positions of the inlets 14a and 14b are different from each other, it is preferable to form the convex portion 15ba also in the blade portion 15b positioned in the projection area region of one of the inlets 14a and 14b in addition to a region in which the respective projection area regions of the inlets 14a and 14b overlap with each other. In the air sucking region, the air can be caused to flow more smoothly in the centrifugal direction.

As shown in FIG. 4(a), the convex portion 15ba is formed on the positive pressure face P of the blade portion 15b which is positioned in the projection area region of the centrifugal fan 15. The convex portion 15ba is formed on an almost center in a transverse direction to be a direction of the rotating shaft 16 in the blade portion 15b (see FIG. 2(b)).

It is preferable that a resin material such as polyphenylene sulfide (PPS), polybutylene terephthalate (PBT) or polyethylene terephthalate (PET) should be used for materials of the hub portion 15a and the blade portion 15b to form the convex portion 15ba and the blade portion 15b through an integral mold.

Moreover, FIG. 4(b) shows a cylindrical sectional shape obtained when the blade portion 15b is cut by an outer peripheral surface of a virtual cylinder S having a smaller cylindrical radius than the radius of the inlet 14b by setting, as a central axis, an axis CL of the rotating shaft 16 which is shown in a one-dotted chain line in FIG. 4(a), and the convex portion 15ba has a rectangular sectional shape in which a height THa is greater than a width TWa.

In a region BWc to be an almost center in a transverse direction of the blade portion 15b in which the convex portion 15ba is formed, it is preferable that at least both a distance BWu from an upper end 15bu of the blade portion 15b and a distance BWl from a lower end 15bl should be maintained to be 20% of a total width BW of the blade portion 15b or more by setting a total width BW of the blade portion 15b to be a comparative reference.

The convex portion 15ba is formed in the region BWc to be the almost center in the transverse direction of the blade portion 15b and thus functions as the distributing plate for the air sucked from each of the inlets 14a and 14b disposed opposite to each other. The airs sucked in opposite directions to each other can be prevented from colliding and interfering with each other over the positive pressure face P of the blade portion 15b. Thus, the respective airs can be caused to smoothly flow in the centrifugal direction. Consequently, it is possible to implement a reduction in fan noises and abnormal sounds caused by the generation of a vortex flow or a turbulence in the air sucking region.

In a comparison on an equal fan noise level, moreover, it is possible to increase the rotating speed more greatly. Therefore, an increase in an air quantity and a rise in a static pressure can be easily carried out so that an air blowing capability can be enhanced.

While the convex portion 15ba is started in the position on the inner diameter side by the predetermined distance from the tip 15be of the blade portion 15b on the outside of the projection area region of the inlet 14b and is extended into the projection area region of the inlet 14b, and is linked to the outer peripheral surface of the hub portion 15a over the positive pressure face P of the blade portion 15b, it may be formed to be extended in the centrifugal direction with a slight inclination to an orthogonal direction to the rotating shaft 16 or may be formed to be extended in the centrifugal direction with curving or meandering in the region BWc to be the almost center in the transverse direction of the blade portion 15b.

As described above, particularly, the inlet 14a has an air inlet passage shielded with the coupling portion 18. For this reason, the air sucking area is correspondingly smaller and the air sucking quantity is decreased more greatly as compared with the inlet 14b. Therefore, it is also possible to downward shift the center in the transverse direction of the convex portion 15ba so as to be slightly close to the inlet 14a in the region BWc to be the almost center in the transverse direction of the blade portion 15b, thereby preventing the convex portion 15ba from having a high air course resistance to the air sucked from the inlet 14b having an air sucking quantity which is larger than that of the inlet 14a.

In other words, in the case in which the air inlet passage is shielded with the coupling portion 18 or the case in which the respective radii of the inlets 14a and 14b are different from each other, a central position in the transverse direction of the convex portion 15ba may be shifted and balanced in a vertical direction from the center in the transverse direction of the blade portion 15b in such a manner that the sucked air smoothly flows corresponding to a difference between the air sucking quantities of the inlets 14a and 14b having the air sucking areas which are different from each other.

Also in the case in which the centrifugal fan device 11 according to the invention is mounted on an electronic apparatus and a great difference is made on the air course resistance in the air inlet passage for the air to be sucked between the respective inlets 14a and 14b depending on a mounting state thereof so that a great difference is made on the air sucking quantities of the respective inlets 14a and 14b, the central position in the transverse direction of the convex portion 15ba may be shifted and balanced in the vertical direction from the center in the transverse direction of the blade portion 15b in such a manner that the sucked air flows smoothly corresponding to the difference between the air sucking quantities.

Moreover, it is preferable that the width TWa of the convex portion 15ba should be as small as possible in order to lessen an influence to generate an air course resistance. In order to ensure a sufficient strength to be resistant to an air pressure or a rotating vibration which is received by the convex portion 15ba, it is more preferable that the width TWa of the convex portion 15ba should be set in a range of 0.3 mm to 3.0 mm if an outside dimension of the blade portion 15b has a width on an inner diameter side of 4.6 mm, a width on an outer diameter side of 8.0 mm, a total length of 19.0 mm and a thickness of 0.9 mm, for example.

In addition, it is preferable that the height THa of the convex portion 15ba should be as great as possible in consideration of the function of the distributing plate. If the height THa is excessively great, it functions as a high air course resistance. For this reason, in the case in which the outside dimensions of the blade portion 15b have the width on the inner diameter side of 4.6 mm, the width on the outer diameter side of 8.0 mm, the total length of 19.0 mm and the thickness of 0.9 mm, for example, it is more preferable that the height THa of the convex portion 15ba should be set into a range of 0.3 mm to 3.0 mm.

Although the convex portion 15ba according to the first embodiment has a rectangular sectional shape, furthermore, it may take a triangular, polygonal, semicylindrical or arcuate sectional shape if the predetermined height can be sufficiently ensured.

Next, the contents will be described in more detail with reference to FIGS. 5(a) and 5(b).

First of all, as shown in FIG. 5(a), the convex portion 15ba is started in the position on the inner diameter side by the predetermined distance from the tip 15be of the blade portion 15b on the outside of the projection area region of the inlet 14b and is extended into the projection area region of the inlet 14b, and is linked to the outer peripheral surface of the hub portion 15a over the positive pressure face P of the blade portion 15b.

When the blade portion 15b is rotated at a high speed in the direction designated as the rotating direction R, the air passing through the inlet 14a positioned below (see FIG. 2(b)) is sucked upward into the inner diameter side of the blade portion 15b as shown in a broken arrow LF and then flows into the surface of the positive pressure face P of the blade portion 15b. However, the convex portion 15ba positioned on the almost center in the transverse direction of the positive pressure face P acts as an air course resistor to the air which flows therein and thus functions as the distributing plate. Therefore, the direction of the air is changed to be almost perpendicular so that the air flows in the centrifugal direction along the longitudinal direction of the blade portion 15b and joins an air flow shown in a broken arrow UF at the outer diameter side of the air sucking region, and finally passes through the positive pressure face P side which is close to the tip 15be and is pushed out in an outer peripheral direction.

On the other hand, the air passing through the inlet 14b positioned above (see FIG. 2(b) is sucked downward into the inner diameter side of the blade portion 15b as shown in the broken arrow UF and then flows into the surface of the positive pressure face P of the blade portion 15b. However, the convex portion 15ba positioned on the almost center in the transverse direction of the positive pressure face P acts as an air course resistor to the air which flows therein and thus functions as the distributing plate. Therefore, the direction of the air is changed to be almost perpendicular so that the air flows in the centrifugal direction along the longitudinal direction of the blade portion 15b and joins an air flow shown in the broken arrow LF in the region provided on the outside of the air sucking region, and finally passes through the positive pressure face P side which is close to the tip 15be and is pushed out in the outer peripheral direction.

Accordingly, the airs sucked in the opposite directions to each other can be prevented from colliding and interfering with each other over the positive pressure face P of the blade portion 15b and are caused to smoothly flow in the centrifugal direction. Therefore, it is possible to implement a reduction in fan noises and abnormal sounds which are caused by the generation of a vortex flow or a turbulence in the air sucking region.

As shown in FIG. 5(b), moreover, the convex portion 15ba positioned on the positive pressure face P of the blade portion 15b is started in a position on an inner diameter side by a predetermined distance from the tip 15be of the blade portion 15b in a region on an outer diameter side of a circular arc shown in a two-dotted chain line on the outside of the projection area region of the inlet 14b in the blade portion 15b and is extended to a region on an inner diameter side of the circular arc shown in the two-dotted chain line in the projection area region of the inlet 14b, and is linked to the outer peripheral surface of the hub portion 15a.

The projection area region of the inlet 14b also overlaps with the projection area region of the inlet 14a. As described above, therefore, the convex portion 15ba formed on the positive pressure face P of the blade portion 15b effectively functions as the distributing plate. At the outside of the projection area region of the inlet 14b to be the region provided on the outside of the circular arc shown in the two-dotted chain line, the respective air flows which are distributed are changed into parallel flows in the centrifugal direction along the longitudinal direction of the blade portion 15b and are thus rectified. Therefore, it is preferable that the convex portion 15ba should be formed to be started in the position on the inner diameter side from the tip 15be of the blade portion 15b by a length la which is longer than 20% of a length La on the positive pressure face P side of the blade portion 15b positioned on the outside of the projection area region. It is possible to effectively reduce an air course resistance on the outside of the air sucking region and to join the parallel flow of the air over the positive pressure face P of the blade portion 15b more smoothly, thereby causing the air to smoothly flow in the centrifugal direction. Consequently, the air quantity can further be increased.

FIG. 6 shows a fan noise (A range noise) of the centrifugal fan device 11 according to the first embodiment of the invention as compared with a fan noise (A range noise) of a conventional centrifugal fan device in which the convex portion 15ba is not formed and shapes and dimensions of the other components are identical in an equal air quantity (0.15 m³/min) together with a centrifugal fan device (not shown) according to a second embodiment which will be described below.

As is apparent from the graph, the fan noise of the conventional centrifugal fan device is 49.0 dBA, while the fan noise of the centrifugal fan device 11 according to the first embodiment of the invention is reduced by 1.5 dBA, that is, 47.5 dBA, and furthermore, the fan noise of the centrifugal fan device according to the second embodiment is reduced by 2.0 dBA, that is, 47.0 dBA.

In other words, the convex portion 15ba formed on the positive pressure face P of the blade portion 15b as described above functions as the distributing plate for the respective airs sucked from the pair of inlets 14a and 14b disposed opposite to each other and the airs sucked in the opposite directions to each other can be prevented from colliding and interfering with each other over the positive pressure face P of the blade portion 15b so that the respective airs can be caused to smoothly flow in the centrifugal direction. Therefore, it is apparent that a reduction in the fan noises and abnormal sounds caused by the generation of a vortex flow or a turbulence in the air sucking region can be implemented.

FIG. 7 shows an air quantity and static pressure characteristic of the centrifugal fan device 11 according to the embodiment of the invention as compared with the conventional centrifugal fan device in which the convex portion 15ba is not formed and the shapes and dimensions of the other components are identical in an identical fan noise (45.0 dBA).

As is apparent from the graph, in the centrifugal fan device 11 according to the first embodiment of the invention, the static pressure characteristic is enhanced more greatly over a total region of the air quantity in an axis of abscissas as compared with the conventional centrifugal fan device.

More specifically, in a comparison on an equal fan noise level, it is possible to increase the rotating speed of the centrifugal fan 15 of the centrifugal fan device 11 more greatly. Therefore, it is indicated that an increase in the air quantity and a rise in the static pressure can be easily carried out, resulting in an enhancement in the air blowing capability.

In the comparison, there is used the conventional centrifugal fan device in which the outside dimension of the blade portion is set to have the width on the inner diameter side of 4.8 mm, the width on the outer diameter side of 7.2 mm, the total length of 22.0 mm and the thickness of 0.8 mm, and the blade portion 15b according to the first embodiment of the invention is also set to have the identical dimensions, and furthermore, the convex portion 15ba to be used is formed in a width TWa of 0.5 mm, a height THa of 1.5 mm, and a distance la from the tip 15be of 7.0 mm.

### Second Embodiment

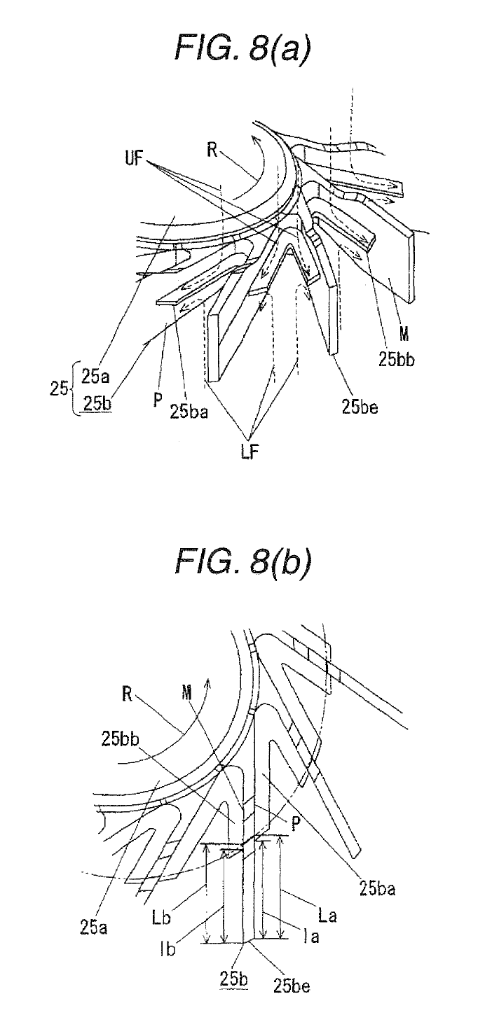

Next, a second embodiment will be described with reference to FIGS. 8(a) and 8(b).

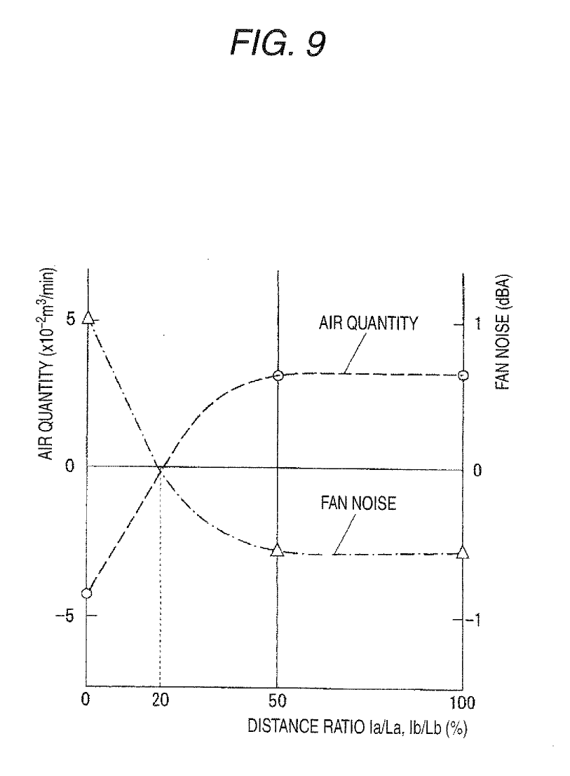

FIG. 8(a) is a partial enlarged perspective view showing a blade portion of a centrifugal fan according to the second embodiment of the invention, FIG. 8(b) is a partial enlarged plan view showing the blade portion of the centrifugal fan according to the second embodiment of the invention, and FIG. 9 is a graph showing an air quantity and a fan noise to a ratio of a length of the blade portion positioned on an outside of a projection area region of an inlet to a distance from a tip of the blade portion to a starting point of a convex portion.

First of all, as shown in FIG. 8(a), a convex portion 25ba is positioned on an almost center in a transverse direction and is started in a position on an inner diameter side by a predetermined distance from a tip 25be of a blade portion 25b on the outside of the projection area region of the inlet (not shown), and is extended into the projection area region of the inlet and is linked to an outer peripheral surface of a hub portion 25a over a positive pressure face P in a rotating direction R of the blade portion 25b. In addition, a convex portion 25bb is positioned on an almost center in a transverse direction and is started in the position on the inner diameter side by the predetermined distance from the tip 25be of the blade portion 25b on the outside of the projection area region of the inlet, and is extended to the projection area region of the inlet (not shown) and is linked to the outer peripheral surface of the hub portion 25a over an opposite surface to a direction designated as the rotating direction R of the blade portion 25b (which will be hereinafter referred to as a negative pressure face M).

When the blade portion 25b is rotated at a high speed in the direction designated as the rotating direction R, an air passing through the inlet (not shown) positioned below is sucked upward into the inner diameter side of the blade portion 25b as shown in an arrow LF of a broken line and then flows into a surface of the positive pressure face P of the blade portion 25b. However, the convex portion 25ba positioned on the almost center in the transverse direction of the positive pressure face P acts as an air course resistor to the air flowing therein and functions as a distributing plate. Therefore, a direction of the air is changed to be almost perpendicular so that the air flows in a centrifugal direction along a longitudinal direction of the blade portion 25b and joins an air flow shown in an arrow UF of a broken line in a region provided on an outside of an air sucking region, and finally passes through the positive pressure face P side which is close to the tip 25be and is pushed out in an outer peripheral direction thereof.

As compared with a quantity of the air flowing into the surface of the positive pressure face P, moreover, an inflow quantity is smaller. However, a part of the air sucked upward also flows into the surface of the negative pressure face M. Similarly, the convex portion 25bb positioned on the almost center in the transverse direction of the negative pressure face M functions as the air course resistor to the air flowing therein and functions as the distributing plate. Therefore, the direction of the air is changed to be almost perpendicular so that the air flows in the centrifugal direction along the longitudinal direction of the blade portion 25b and joins the air flow shown in the arrow UF of the broken line in the region provided on the outside of the air sucking region, and finally passes through the negative pressure face M side which is close to the tip 25be and is pushed out in the outer peripheral direction thereof.

On the other hand, the air passing through the inlet (not shown) positioned above is sucked downward into the inner diameter side of the blade portion 25b as shown in the arrow UF of the broken line and then flows into the surface of the positive pressure face P of the blade portion 25b. However, the convex portion 25ba positioned on the almost center in the transverse direction of the positive pressure face P acts as the air course resistor to the air flowing therein and functions as the distributing plate. Therefore, the direction of the air is changed to be almost perpendicular so that the air flows in the centrifugal direction along the longitudinal direction of the blade portion 25b and joins the air flow shown in the arrow LF of the broken line in the region provided on the outside of the air sucking region, and finally passes through the positive pressure face P side which is close to the tip 25be and is pushed out in the outer peripheral direction thereof.

As compared with the quantity of the air flowing into the surface of the positive pressure face P, moreover, an inflow quantity is smaller. However, a part of the air sucked downward also flows into the surface of the negative pressure face M. Similarly, the convex portion 25bb positioned on the almost center in the transverse direction of the negative pressure face M functions as the air course resistor to the air flowing therein and functions as the distributing plate. Therefore, the direction of the air is changed to be almost perpendicular so that the air flows in the centrifugal direction along the longitudinal direction of the blade portion 25b and joins the air flow shown in the arrow LF of the broken line in the region provided on the outside of the air sucking region, and finally passes through the negative pressure face M side which is close to the tip 25be and is pushed out in the outer peripheral direction thereof.

Accordingly, the convex portion 25ba and the convex portion 25bb are provided on both the positive pressure face P and the negative pressure face M of the blade portion 25b. Consequently, the airs sucked in opposite directions to each other can be prevented from colliding and interfering with each other over the positive pressure face P and the negative pressure face M of the blade portion 25b and can be caused to smoothly flow in the centrifugal direction. Therefore, it is possible to implement a reduction in fan noises and abnormal sounds which are caused by the generation of a vortex flow or a turbulence in the air sucking region.

As shown in FIG. 8(b), moreover, the projection area region of the inlet in the blade portion 25b of the centrifugal fan 25 is indicated as a region on an inner diameter side of a circular arc shown in a two-dotted chain line, and the convex portion 25ba is positioned on the almost center in the transverse direction and is started in the position on the inner diameter side by the predetermined distance from the tip 25be of the blade portion 25b on the outside of the projection area region of the inlet, and is extended into the projection area region of the inlet and is linked to the outer peripheral surface of the hub portion 25a over the positive pressure face P in the rotating direction R of the blade portion 25b. In addition, the convex portion 25bb is positioned on the almost center in the transverse direction and is started in the position on the inner diameter side by the predetermined distance from the tip 25be of the blade portion 25b on the outside of the projection area region of the inlet, and is extended into the projection area region of the inlet and is linked to the outer peripheral surface of the hub portion 25a over the opposite surface to the direction designated as the rotating direction R of the blade portion 25b (which will be hereinafter referred to as the negative pressure face M).

As described above, the convex portion 25ba formed on the positive pressure face P of the blade portion 25b and the convex portion 25bb formed on the negative pressure face M of the blade portion 25b effectively function as the distributing plates, respectively. At the outside of the projection area region of the inlet to be a region provided on the outside of the circular arc shown in the two-dotted chain line, the respective air flows which are distributed are changed into parallel flows in the centrifugal direction along the longitudinal direction of the blade portion 25b and are thus rectified. Therefore, it is preferable that the convex portion 25ba should be formed to be started in the position on the inner diameter side from the tip 25be of the blade portion 25b by a length la which is longer than 20% of a length La on the positive pressure face P side of the blade portion 25b positioned on the outside of the projection area region and the convex portion 25bb should be formed to be started in the position on the inner diameter side from the tip 25be of the blade portion 25b by a length lb which is longer than 20% of a length Lb on the negative pressure face M side of the blade portion 25b positioned on the outside of the projection area region. It is possible to effectively reduce an air course resistance in the region provided on the outside of the air sucking region and to join the parallel flows of the air over the positive pressure face P and the negative pressure face M in the blade portion more smoothly, thereby causing the air to smoothly flow in the centrifugal direction. Consequently, the air quantity can further be increased.

Moreover, FIG. 9 shows a change in an air quantity and a fan noise which is generated in a simultaneous change in both a ratio (la/La) of the length La on the positive pressure face P side of the blade portion 25b positioned on the outside of the projection area region of the inlet to the distance la from the tip 25be of the blade portion 25b to the starting point of the convex portion 25ba and a ratio (lb/Lb) of the length Lb on the negative pressure face M side of the blade portion 25b positioned on the outside of the projection area region of the inlet to the distance lb from the tip 25be of the blade portion 25b to the starting point of the convex portion 25bb in the case in which the convex portion 25ba is formed on the positive pressure face P of the blade portion 25b and the convex portion 25bb is formed on the negative pressure face M.

For a comparison, there are shown a difference from an air quantity (0.104 m³/min) in an operation on a condition that an identical fan noise (35.0 dBA) is made and a difference from a fan noise (36.1 dBA) in an operation on a condition that an identical air quantity (0.110 m³/min) is obtained by using a conventional centrifugal fan having a blade portion taking a flat shape in which a convex portion is formed on neither the positive pressure face P nor the negative pressure face M.

As is apparent from the drawing, the convex portion 25ba is formed to be started in the position on the inner diameter side from the tip 25be of the blade portion 25b by the longer distance la than 20% of the length La on the positive pressure face P side of the blade portion 25b positioned on the outside of the projection area region of the inlet and the convex portion 25bb is formed to be started in the position on the inner diameter side from the tip 25be of the blade portion 25b by the longer distance lb than 20% of the length Lb on the negative pressure face M side of the blade portion 25b positioned on the outside of the projection area region of the inlet. Consequently, both the air quantity and the fan noise can be improved more greatly than those in the case in which the conventional centrifugal fan is used.

In the comparison, the measurement is carried out by using outside dimensions of the blade portion of the conventional centrifugal fan device in which a width on an inner diameter side of 4.8 mm, a width on an outer diameter side of 7.2 mm, a total length of 22.0 mm and a thickness of 0.8 mm are set, setting the blade portion 15b according to the second embodiment of the invention to have the identical dimensions, and furthermore, setting the convex portion 25ba and the convex portion 25bb to be constant, that is, a width TWa of 2.0 mm and a height THa of 1.2 mm and varying the ratio of the distance la to the length La and the ratio of the distance lb to the length Lb in a range of 0% to 100%.

Moreover, the operation is carried out on a condition that an identical fan noise (35.0 dBA) is obtained in the measurement of the air quantity and the operation is carried out on the condition that an equal air quantity (0.110 m³/min) is obtained in the measurement of the fan noise.

As described above, moreover, FIG. 6 shows a comparison of a fan noise (A range noise) of the centrifugal fan device (not shown) according to the second embodiment in which the centrifugal fan 25 is combined with the other components described in the first embodiment to a fan noise (A range noise) of the conventional centrifugal fan device in an equal air quantity (0.15 m³/min) together with a fan noise (A range noise) of the centrifugal fan device 11 according to the first embodiment of the invention.

As is apparent from the graph, the fan noise of the conventional centrifugal fan device is 49.0 dBA, while the fan noise of the centrifugal fan device according to the second embodiment of the invention is reduced to be 47.0 dBA which is further smaller than the fan noise of the centrifugal fan device 11 according to the first embodiment of the invention by 0.5 dBA.

In other words, as described above, the convex portion 25ba formed on the positive pressure face P of the blade portion 25b and the convex portion 25bb formed on the negative pressure face M of the blade portion 25b function as the distributing plates for the respective airs sucked from the pair of inlets (not shown) disposed opposite to each other, and the airs sucked in opposite directions to each other can be prevented from colliding and interfering with each other over the positive pressure face P and the negative pressure face M in the blade portion 25b and can be caused to smoothly flow in the centrifugal direction. Therefore, it is apparent that a reduction in fan noises and abnormal sounds which are caused by the generation of a vortex flow or a turbulence in the air sucking region can be implemented still more greatly.

### Third Embodiment

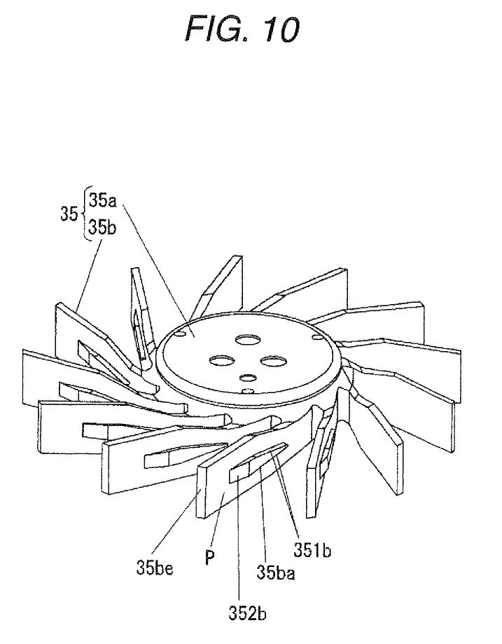

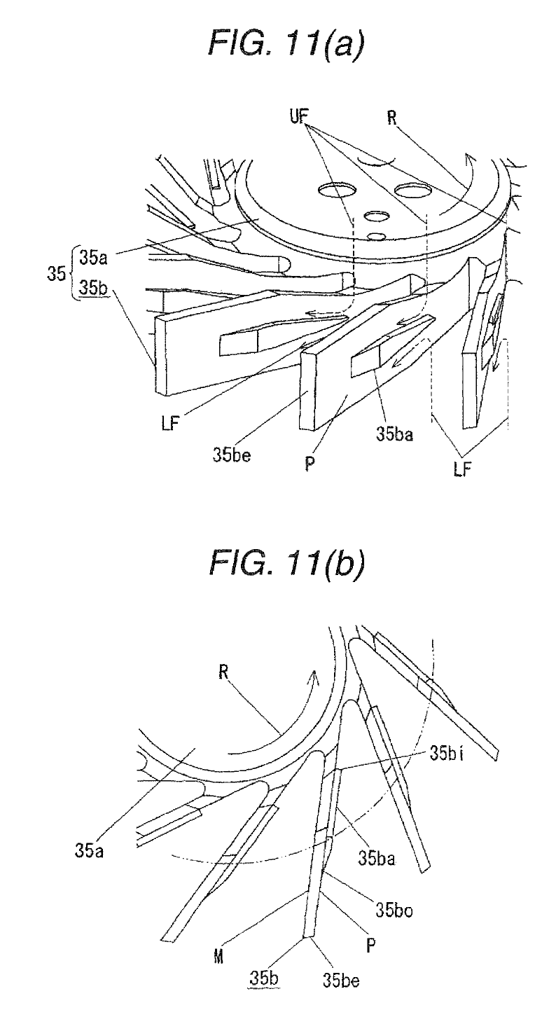

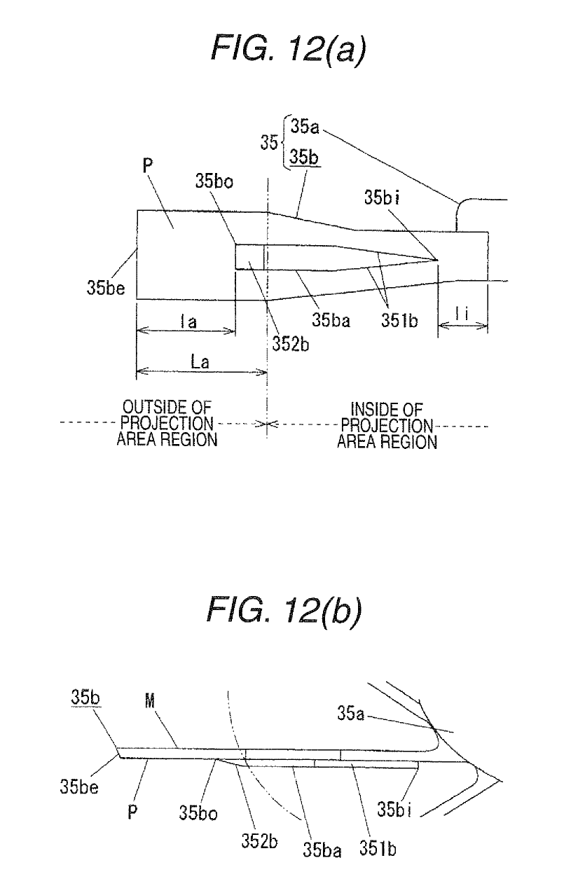

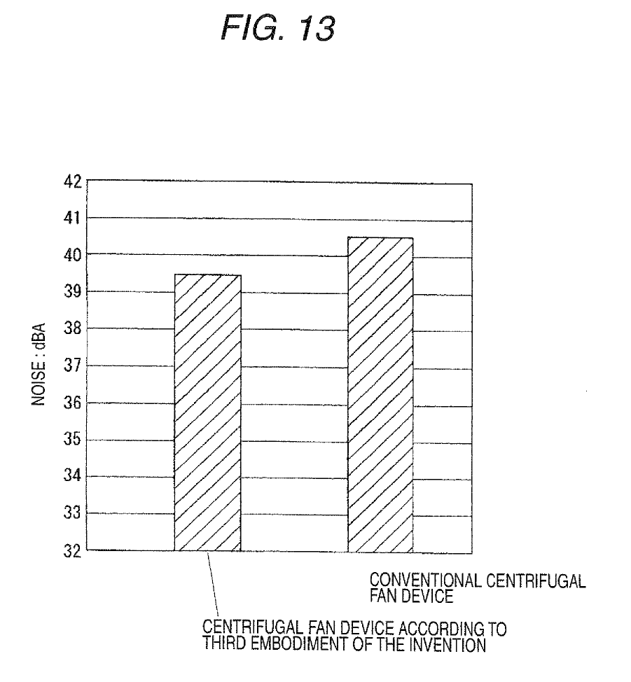

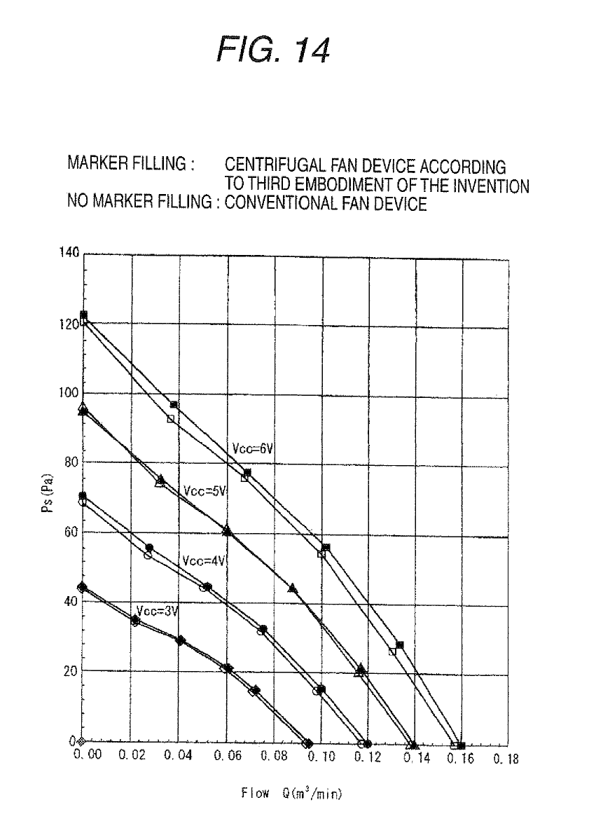

FIG. 10 is a perspective view showing a centrifugal fan according to a third embodiment of the invention, FIG. 11(a) is a partial enlarged perspective view showing a blade portion of the centrifugal fan according to the third embodiment of the invention, FIG. 11(b) is a partial enlarged plan view showing the blade portion of the centrifugal fan according to the third embodiment of the invention, FIG. 12(a) is a front view showing the blade portion of the centrifugal fan according to the third embodiment of the invention as seen from a positive pressure face side, FIG. 12(b) is a plan view showing the blade portion of the centrifugal fan according to the third embodiment of the invention as seen from just above, FIG. 13 is a comparative graph showing fan noises (A range noises) in an equal air quantity, and FIG. 14 is a comparative graph showing air quantity and static pressure characteristics in the case in which an identical fan casing and an identical driving circuit are used.

First of all, in FIG. 10, a convex portion 35ba is formed on a face (hereinafter 5 referred to as a positive pressure face P) in a direction designated as a rotating direction R of all blade portions 35b as a projection area region in which an open region of an inlet (not shown) is projected into a direction of a centrifugal fan 35 in parallel with a direction of a rotating shaft.

The convex portion 35ba is positioned on an almost center in a transverse direction and is started in a position on an inner diameter side by a predetermined distance from a tip 35be of the blade portion 35b on an outside of the projection area region of the inlet and is extended into the projection area region of the inlet, and is terminated in a position on an outer diameter side by a predetermined distance from an outer peripheral surface of a hub portion 35a over the positive pressure face P in the rotating direction R of the blade portion 35b, which will be described below in detail.

Furthermore, the convex portion 35ba includes a first inclined portion 351b having a width reduced gradually in a direction of the hub portion 35a at the inner diameter side and a second inclined portion 352b having a height reduced gradually in a direction of the tip 35be of the blade portion 35b at the outer diameter side.

The first inclined portion 351b can gradually increase a function of an air distributing plate at the outer diameter side of an air sucking region in which airs sucked from the respective inlets in opposite directions to each other collide with each other over a face of the blade portion 35b comparatively often. Therefore, it is possible to simultaneously implement a reduction in fan noises and abnormal sounds and an increase in an air quantity more effectively.

In the second inclined portion 352b, moreover, a flow of the air distributed and flowing is changed into a parallel flow in a centrifugal direction in a fan casing (not shown) and is thus rectified, and an air course resistance on the outside of the air sucking region is gradually reduced and they are caused to join each other little by little without generating a vortex flow or a turbulence. Thus, the air can be caused to flow in the centrifugal direction more smoothly. Therefore, the air quantity can be increased more greatly.

Next, the contents will be described in more detail with reference to FIGS. 11(a) and 11(b).

First of all, as shown in FIG. 11(a), the convex portion 35ba is formed to be positioned on the almost center in the transverse direction and to have an outer diameter side tip 35bo (see FIGS. 12(a) and 12(b)) in the position on the inner diameter side by the predetermined distance from the tip 35be of the blade portion 35b at the outside of the projection area region of the inlet, to be extended into the projection area region of the inlet and to have an inner diameter side tip 35bi (see FIGS. 12(a) and 12(b)) in a position on an outer diameter side by a predetermined distance from the outer peripheral surface of the hub portion 35a over the positive pressure face P in the rotating direction R of the blade portion 35b.

When the blade portion 35b is rotated at a high speed in the direction designated as the rotating direction R, the air passing through the inlet (not shown) positioned below is sucked into the inner diameter side of the blade portion 35b upward as shown in an arrow LF of a broken line and then flows into a surface of the positive pressure face P of the blade portion 35b. However, the convex portion 35ba positioned on the almost center in the transverse direction of the positive pressure face P becomes an air course resistor to the flowing air and functions as the distributing plate. Therefore, a direction of the air is changed to be almost perpendicular so that the air flows in the centrifugal direction along a longitudinal direction of the blade portion 35b.

Moreover, the convex portion 35ba is formed to have the outer diameter side tip 35bo in the position on the inner diameter side by the predetermined distance from the tip 35be of the blade portion 35b at the outside of the projection area region of the inlet. Therefore, the air course resistance is reduced to cause the air to smoothly join an air flow shown in an arrow UF of a broken line over the surface of the blade portion 35b and to smoothly flow in the centrifugal direction at the outside of the air sucking region. Consequently, the air finally passes through the positive pressure face P side which is close to the tip 35be and is pushed out in an outer peripheral direction thereof.

In addition, the convex portion 35ba is formed to have the tip 35bi on the inner diameter side in the position at the outer diameter side by the predetermined distance from the outer peripheral surface of the hub portion 35a in the projection area region. Therefore, the air course resistance can be effectively reduced at the inner diameter side of the air sucking region in which the collision of the airs sucked from the respective inlets in the opposite directions to each other is carried out comparatively rarely over the surface of the blade portion 35b. Consequently, the air quantity can be increased more greatly.

On the other hand, the air passing through the inlet (not shown) positioned above is sucked into the inner diameter side of the blade portion 35b downward as shown in the arrow UF of the broken line and then flows into the surface of the positive pressure face P of the blade portion 35b. However, the convex portion 35ba positioned on the almost center in the transverse direction of the positive pressure face P becomes the air course resistor to the flowing air and functions as the distributing plate. Therefore, the direction of the air is changed to be almost perpendicular so that the air flows in the centrifugal direction along a longitudinal direction of the blade portion 35b and smoothly joins the air flow shown in the arrow LF of the broken line in the region provided on the outside of the air sucking region, and finally passes through the positive pressure face P side which is close to the tip 35be and is pushed out in the outer peripheral direction thereof.

As shown in FIG. 11(b), moreover, the projection area region of the inlet (not shown) in the blade portion 35b is provided on an inner diameter side of a circular arc shown in a two-dotted chain line, and the convex portion 35ba is formed on the almost center in the transverse direction of the blade portion 35b so as to have the outer diameter side tip 35bo in a position on the inner diameter side by the predetermined distance from the tip 35be of the blade portion 35b at the outside of the projection area region of the inlet, to be extended into the projection area region of the inlet and to have the inner diameter side tip 35bi in the position on the outer diameter side by the predetermined distance from the outer peripheral surface of the hub portion 35a.

As shown in FIG. 12(a), a region on an inner diameter side of a two-dotted chain line is an inside of the projection area region of the inlet and a region on an outer diameter side of the two-dotted chain line is an outside of the projection area region of the inlet. The convex portion 35ba is positioned on the almost center in the transverse direction on the positive pressure face P of the blade portion 35b and is formed to have the outer diameter side tip 35bo in a position on the inner diameter side by a distance la from the tip 35be of the blade portion 35b at the outside of the projection area region of the inlet, to be extended into the projection area region of the inlet and to have the inner diameter side tip 35bi in a position on the outer diameter side by a distance li from the outer peripheral surface of the hub portion 35a over the positive pressure face P of the blade portion 35b.

The convex portion 35ba has the first inclined portion 351b having the width reduced gradually in the direction of the hub portion 35a at the inner diameter side and has the second inclined portion 352b having the height reduced gradually in the direction of the tip 35be of the blade portion 35b at the outer diameter side.

The first inclined portion 351b can gradually increase the function of the air distributing plate at the outer diameter side of the air sucking region in which the airs sucked from the respective inlets in opposite directions to each other collide with each other comparatively often over the surface of the blade portion 35b. Therefore, it is possible to simultaneously implement a reduction in fan noises and abnormal sounds and an increase in an air quantity more effectively.

In the second inclined portion 352b, moreover, a flow of the air distributed and flowing is changed into a parallel flow in a centrifugal direction in a fan casing (not shown) and is thus rectified, and an air course resistance on the outside of the air sucking region is gradually reduced and they are caused to join each other little by little without generating a vortex flow or a turbulence. Thus, the air can be caused to flow in the centrifugal direction more smoothly. Therefore, the air quantity can be increased more greatly.

Furthermore, it is preferable that the convex portion 35ba should be formed to have the outer diameter side tip 35bo in the position on the inner diameter side from the tip 35be by a distance la which is longer than 20% of a length La of the blade portion 35b positioned on the outside of the projection area region, and the air course resistance on the outside of the air sucking region can be effectively reduced and the air parallel flows can be caused to join each other more smoothly over the positive pressure face P of the blade portion 35b, thereby causing the air to smoothly flow in the centrifugal direction. Therefore, the air quantity can further be increased.

In addition, the total width of the blade portion 35b is gradually increased in the centrifugal direction in the projection area region of either of the pair of inlets so that the air course resistance can be effectively reduced on the inner diameter side of the air sucking region in which the collision of the airs sucked from the respective inlets in the opposite directions to each other is carried out comparatively rarely over the surface of the blade portion 35b. Consequently, the air quantity can be increased more greatly.

It is preferable that a maximum width of the convex portion 35ba should be as small as possible in order to lessen the influence to generate the air course resistance, which is not shown. In order to ensure a sufficient strength as to be resistant to a wind pressure or a rotational vibration which is received by the convex portion 35ba, it is more preferable to set a maximum width TWa of the convex portion 35ba into a range of 0.3 mm to 3.0 mm if an outside dimension of the blade portion 35b has a width on an inner diameter side of 4.8 mm, a width on an outer diameter side of 7.2 mm, a total length of 22.0 mm and a thickness of 0.8 mm, for example.

Moreover, it is preferable that a maximum height of the convex portion 35ba should be as great as possible in consideration of the function of the distributing plate. If the maximum height is excessively great the convex portion 35ba acts as a great air course resistor. For this reason, it is more preferable that the maximum height THa of the convex portion 35ba should be set into a range of 0.3 mm to 3.0 mm if the outside dimension of the blade portion 35b has a width on an inner diameter side of 4.6 mm, a width on an outer diameter side of 8.0 mm, a total length of 19.0 mm and a thickness of 0.9 mm, for example.

In addition, FIG. 13 shows a comparison of a fan noise (A range noise) of the centrifugal fan device (not shown) according to the third embodiment of the invention to a fan noise (A range noise) of the conventional centrifugal fan device in which the convex portion 35ba is not formed and the other components have identical shapes and dimensions in an equal air quantity (0.138 m³/min).

As is apparent from the graph, the fan noise of the conventional centrifugal fan device is 40.6 dBA, while the fan noise of the centrifugal fan device according to the third embodiment of the invention is reduced to be 39.4 dBA which is smaller by 1.2 dBA.

In other words, as described above, the convex portion 35ba formed on the positive pressure face P of the blade portion 35b functions as the distributing plate for the air sucked from each of the pair of inlets disposed opposite to each other, and the airs sucked in opposite directions to each other can be prevented from colliding and interfering with each other over the positive pressure face P of the blade portion 35b. Thus, the respective airs can be caused to smoothly flow in the centrifugal direction. Consequently, it is apparent that a reduction in fan noises and abnormal sounds caused by the generation of a vortex flow or a turbulence in the air sucking region can be implemented.

Moreover, FIG. 14 shows a comparison carried out by using an identical fan casing and an identical driving circuit between an air quantity and static pressure characteristic of the centrifugal fan device (not shown) according to the third embodiment of the invention and that of the conventional centrifugal fan device in which the convex portion 35ba is not formed and the shapes and dimensions of the other components are identical.

The air quantity and static pressure characteristic is measured in the respective cases in which a source voltage Vcc is set to be 3V, 4V, 5V and 6V, and marker filling indicates the air quantity and static pressure characteristic of the centrifugal fan device according to the third embodiment of the invention and no marker filling indicates the air quantity and static pressure characteristic of the conventional centrifugal fan device.

As is apparent from the graph, in contrast to the air quantity and static pressure characteristic of the conventional centrifugal fan device, the static pressure characteristic in the air quantity and static pressure characteristic of the centrifugal fan device according to the third embodiment of the invention is enhanced over a whole region of the air quantity in an axis of abscissas in all of the cases in which the source voltage Vcc is set to be 3V, 4V, 5V and 6V.

More specifically, it is indicated that an increase in the air quantity and a rise in the static pressure can easily be carried out so that an air blowing capability can be enhanced in the case in which the comparison is made by using the identical fan casing and driving circuit.

In the case in which the comparison is made on an equal fan noise level, moreover, it is possible to increase a rotating speed more greatly. Therefore, the increase in the air quantity and the rise in the static pressure can be easily carried out so that the air blowing capability can be enhanced.

In the comparison, there is used the blade portion of the conventional centrifugal fan device having the outer dimensions in which the width on the inner diameter side of 4.8 mm, the width on the outer diameter side of 7.2 mm, the total length of 22.0 mm and the thickness of 0.8 mm are set, the blade portion 35b according to the third embodiment of the invention is also set to have the same dimensions, and furthermore, the positive pressure face P to be used has the convex portion 35ba in which a maximum width TWa of 2.6 mm, a maximum height THa of 0.6 mm, a distance la from the tip 35be of 5.0 mm and a distance li from the outer peripheral surface of the hub portion 35a of 6.0 mm are set.

### Fourth Embodiment

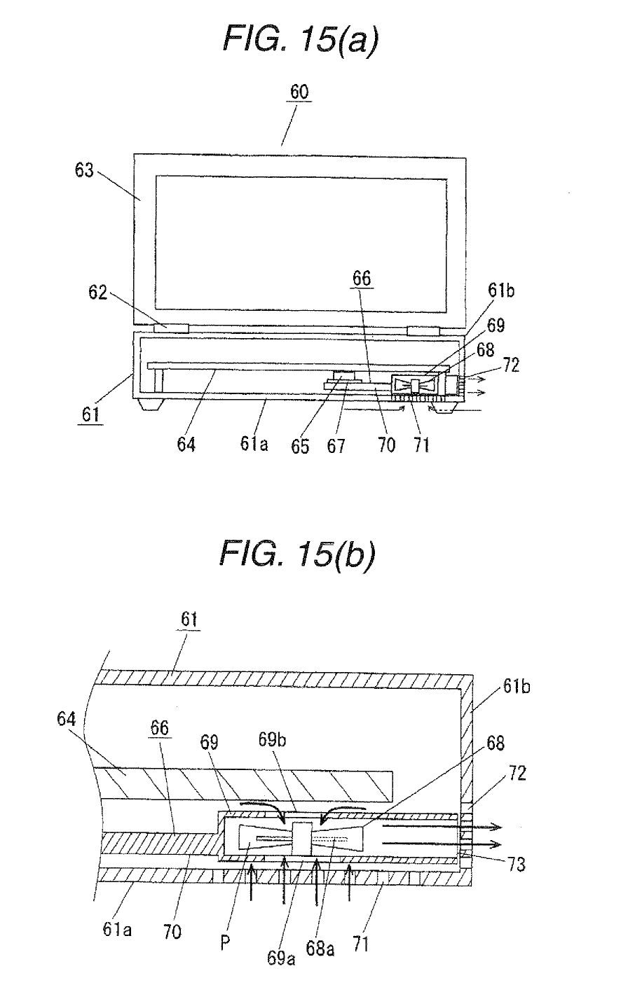

FIG. 15(a) is a view showing an inner part of a housing of an electronic apparatus according to a fourth embodiment of the invention and FIG. 15(b) is a partial sectional view showing the inner part of the housing of the electronic apparatus according to the fourth embodiment of the invention.

An electronic apparatus 60 is a notebook PC having such a structure that an opening and closing type liquid crystal display 63 is rotationally supported on a hinge mechanism 62 provided on an end of a body device 61 having an operating portion.

A heat generating electronic component 65 such as an MPU or a CPU to be cooled is mounted on a lower side surface of a circuit board 64 disposed in the housing of the body device 61 in the electronic apparatus 60, and furthermore, a centrifugal fan device 66 for cooling them at the same time is loaded.

The centrifugal fan device 66 shown in FIG. 15(a) has a heating portion 67 linked thereto in addition to the structure described in the first embodiment and is disposed in a predetermined position on the lower side surface of the circuit board 64 in such a manner that the heating portion 67 linked to the centrifugal fan device 66 is thermally connected to the heat generating electronic component 65 mounted on the lower side surface of the circuit board 64.

As described in the first embodiment, the centrifugal fan device 66 includes a centrifugal fan 68 for sending the air by a rotation of a plurality of blades and a fan casing 69 which rotatably accommodates the centrifugal fan 68 therein and is linked to the heating portion 67 connected thermally to the heat generating electronic component 65, and serves to radiate a heat transferred from the heat generating electronic component 65 to the fan casing 69 by sending the air through the centrifugal fan 68. The heat of the heating portion 67 connected thermally to the heat generating electronic component 65 is transferred through a heat transporting portion 70 and is thus transported to an air blowing path in the fan casing 69, and the air flowing through the air blowing path and the fan casing 69 directly come in contact with each other. Therefore, there is a function for promoting a heat exchange more greatly and efficiently radiating a heat.

A bottom face 61a of the housing of the body device 61 in the electronic apparatus 60 has a plurality of vents 71 provided in places corresponding to a position in which the fan casing 69 is to be attached. Therefore, an external cold air at a lower side of the bottom face 61a of the housing in the body device 61 passes through the vents 71 and is sucked into the air blowing path in the fan casing 69 as shown in an arrow by the air sucking function of the centrifugal fan 68 and the heat is transferred from the heating portion 67 through the heat transporting portion 70 during a flow in the fan casing 69, and the air receives the heat transported through the fan casing 69 by a heat exchange, and is blown out of a vent 72 of a side surface 61b of the housing in the body device 61 as shown in an arrow.

In more detail, FIG. 15(b) is a partial sectional view taken in an air blowing direction from an outlet 73 of the centrifugal fan device 66 in FIG. 15(a), illustrating, in detail, a state in which the heat generating electronic component 65 to be cooled is mounted on the lower side surface of the circuit board 64 disposed in the housing of the body device 61 in the electronic apparatus 60 and the centrifugal fan 66 for cooling the heat generating electronic component 65 is loaded.

As described in the first embodiment, the centrifugal fan device 66 includes the centrifugal fan 68 for sending the air by a rotation of a blade portion having a convex portion 68a formed on a positive pressure face P and the fan casing 69 which rotatably accommodates the centrifugal fan 68 and has a pair of inlets 69a and 69b disposed opposite to each other with the centrifugal fan 68 interposed therebetween. Therefore, fan noises and abnormal sounds of the centrifugal fan device 66 are reduced. Therefore, it is possible to enhance a silence in an operation of the electronic apparatus 60 and to provide a more comfortable working environment to an operator.

In the description of each of the embodiments, the scope of the invention is not restricted to only the dimensions, numerical quantities, materials and shapes of the respective components and their relative arrangement if the purport that restrictions are imposed thereon is not described, and they are only illustrative for the description of the embodiments and can be variously changed.

In particular, the dimensions, numerical quantities and shapes of the hub portion, the blade portion and the convex portion in the centrifugal fan to be a main component and their relative arrangement are not restricted to only the embodiments. If desirable functions and advantages are obtained, particularly, it is sufficient that the convex portion is formed in the projection area region of one of the pair of inlets of the cover and the frame, and a plurality of convex portions may be discontinuously formed for each of the blade portions, the width, the height and the sectional shape may be nonuniform in the longitudinal direction, and the convex portion may be formed in only a part of the blade portions in place of all of the blade portions of the centrifugal fan.

Moreover, the shape of the blade portion is not particularly restricted but may take such a shape that it is vertically asymmetrical in a transverse direction, a total width is uniform from the inner diameter side to the outer diameter side, a shape in an orthogonal direction to a rotating axis is not straight but is curved on the inner diameter side, the outer diameter side or an intermediate part or a circular plate or a rib is provided in the tip part of the blade portion.

Furthermore, the external shape of the fan casing is not particularly restricted but may be an almost circle, an almost triangle, an almost square, an almost parallelogram or other various polygons, and the outlet may be provided in two directions or more in place of one direction.

In addition, the fan casing is not constituted by only the cover and the frame but may have such a structure that a heating portion for thermally connecting a heat generating electronic component to a part of the cover or the frame is provided, a heat sink formed by a radiator fin having a heat radiating property is integrally provided by a die casting mold or press molding, and furthermore, a heat transporting member such as a heat pipe or a heat conducting sheet for efficiently transporting a heat therebetween is separately provided.

This application is based upon and claims the benefit of priorities of Japanese Patent Application No. 2006-323401 filed on Nov. 30, 2006 and No. 2007-087466 filed on Mar. 29, 2007, the contents of which are incorporated herein by reference in its entirety.

1. A centrifugal fan device comprising:
a centrifugal fan including a hub portion having a cylindrical outer peripheral surface and a plurality of blade portions extended in a centrifugal direction from the outer peripheral surface of the hub portion, and
a fan casing which rotatably accommodates the centrifugal fan therein and includes a pair of inlets having an equal diameter and disposed opposite to each other with the centrifugal fan interposed therebetween,
wherein a convex portion is provided on a positive pressure face of the blade portion for receiving air when the blade portion is rotated, and one of ends of the convex portion is disposed on an inside of a projection region of the blade portion surrounded by an outer periphery of the inlet projected onto the blade portion, and the other end of the convex portion is disposed on an outside of the projection region and an inside separated from a tip of the blade portion by a first predetermined distance.

2. The centrifugal fan device according to claim 1, wherein one of the ends of the convex portion is provided in contact with the hub portion.

3. The centrifugal fan device according to claim 1, wherein the convex portion is positioned on an almost center in a transverse direction of the blade portion.

4. The centrifugal fan device according to claim 1, wherein the convex portion is provided on a negative pressure face at an opposite side to the positive pressure face.

5. The centrifugal fan device according to claim 1, wherein the first predetermined distance is equal to or greater than 20% of a length of the blade portion provided on the outside of the projection region.

6. The centrifugal fan device according to claim 5, wherein the first predetermined distance is 50% to 100% of the length of the blade portion provided on the outside of the projection region.

7. The centrifugal fan device according to claim 6, wherein when the first predetermined distance is 100% of the length of the blade portion provided on the outside of the projection region, the other end of the convex portion is disposed on a boundary line between the inside and the outside of the projection region.

8. The centrifugal fan device according to claim 1, wherein one of the ends of the convex portion is positioned on an outside separated from the outer peripheral surface of the hub portion by a second predetermined distance.

9. The centrifugal fan device according to claim 8, wherein a first inclined portion is provided on one of the end sides of the convex portion and a second inclined portion is provided on the other end side of the convex portion.

10. The centrifugal fan device according to claim 9, wherein the first inclined portion is inclined in such a manner that a width in a direction of a short side of the convex portion is gradually reduced toward one of the ends of the convex portion.

11. The centrifugal fan device according to claim 9, wherein the second inclined portion is inclined in such a manner that a height of the convex portion protruded from the positive pressure face is gradually reduced toward the other end of the convex portion.

12. A centrifugal fan device comprising:
a centrifugal fan including a hub portion having a cylindrical outer peripheral surface and a plurality of blade portions extended in a centrifugal direction from the outer peripheral surface of the hub portion, and
a fan casing which rotatably accommodates the centrifugal fan therein and includes a pair of inlets having an equal diameter and disposed opposite to each other with the centrifugal fan interposed therebetween,
wherein a convex portion is provided on a positive pressure face of the blade portion for receiving air when the blade portion is rotated, and the convex portion is positioned on an inside of an end of the blade portion.

13. An electronic apparatus comprising the centrifugal fan device according to claim 1.

14. An electronic apparatus comprising the centrifugal fan device according to claim 12.
